(19) United States
(12) Patent Application Publication
(10) Pub. No.: US 2026/0361326 A1
(43) Pub. Date: Nov. 12, 2026

(54) ARKE - A LOW SWAP SOFTWARE DEFINED TRANSPONDER FOR MARS AND LUNAR APPLICATIONS

(71) Applicant: California Institute of Technology, Pasadena, CA (US)

(72) Inventors: Zaid J. Towfic, Pasadena, CA (US); Brett P. Douglas, Pasadena, CA (US); Andrew C. Daniel, Pasadena, CA (US); Frank Chaqueco, Pasadena, CA (US); Nacer E. Chahat, Pasadena, CA (US); Carl Spurgers, Pasadena, CA (US); Mark Taylor, Pasadena, CA (US); Adrian J. Tang, Pasadena, CA (US); Emmanuel Decrossas, Pasadena, CA (US)

(73) Assignee: California Institute of Technology, Pasadena, CA (US)

(21) Appl. No.: 19/674,922

(22) Filed: May 12, 2026

Related U.S. Application Data
(60) Provisional application No. 63/804,113, filed on May 12, 2025.

(51) Int. Cl. H04B 1/00; H03L 7/08; H04B 1/04; H04L 25/03

(52) U.S. Cl. CPC H04B 1/0078; H03L 7/08; H04B 1/04; H04L 25/03; H04B 2001/0408

(57) ABSTRACT

A communication device including an integrated circuit programmable to signal process a baseband signal and output a control signal according to a communication protocol; a radio frequency integrated circuit (RFIC) operable to mix the baseband signal with a local oscillator to modulate an RF carrier with the baseband signal or demodulate the baseband signal from an RF signal; an antenna having a feed to receive the RF carrier or output the RF signal; an RF switch; a solid state power amplifier operable to amplify the RF carrier; a low noise amplifier operable to amplify the RF signal; wherein the control signal controls the RF switch to select between a transmission mode and reception mode according to the communication protocol executed in the integrated circuit.

### CROSS REFERENCE TO RELATED APPLICATIONS

This application claims the benefit under 35 U.S.C. Section 119(e) of U.S. Provisional Application No. 63/804, 113, filed May 12, 2025, by Zaid J. Towfic; Brett P. Douglas; Andrew C. Daniel; Frank Chaqueco; Nacer E. Chahat; Carl Spurgers; Mark Taylor; Adrian J. Tang; and Emmanuel Decrossas, entitled “Arke-A Low SWaP Software Defined Transponder For Mars and Lunar Applications,” (CIT-9314-P), which application is incorporated by reference herein.

### STATEMENT REGARDING FEDERALLY SPONSORED RESEARCH AND DEVELOPMENT

This invention was made with government support under Grant No. 80NM0018D0004 awarded by NASA (JPL). The government has certain rights in the invention.

### BACKGROUND OF THE INVENTION

### Field of the Invention.

The present disclosure relates to (e.g., radio) communication systems, methods of making the same, and systems for performing communications using such communication systems.

### Description of the Related Art.

There is a need for radio communication systems that target small space platforms that can interface directly with relay networks without the need to use surface-based intermediate relays for communications.

After the successful demonstration of very small Mars platforms through the Ingenuity helicopter, NASA's Mars Exploration Program has emphasized the vital role of low-cost and smaller agile platforms in the future portfolio of Mars missions. As the program advances to handle such missions, there is a need for innovative radio communication systems targeting these small platforms to directly interface with the Mars Relay Network (MRN) without the need to use surface-based intermediate relays for communications, as done previously with the Ingenuity helicopter.

Compared to prior transponders on Mars missions, low-SWaP platforms require transponders that are less than 500 g and less than 10 W DC power. In comparison, the Electra-Lite transponder on the M 2020 rover is 3 kg and utilizes 65 W of DC power, including 15 W of DC power when in standby mode. Compared to previous JPL transponders, the Arke transponder described herein utilizes RFIC technology to minimize the size and weight requirements of the transponder.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1 depicts a block diagram of the communication device.

FIG. 2 depicts a component layout.

FIG. 3 illustrates a package layout showing the digital section and the shielded analog and RF section.

FIG. 4 illustrates example chip layouts.

FIG. 5 illustrates an example communication system including a transponder.

FIG. 6 illustrates an example software defined radio system including the transponder.

FIG. 7 is a flowchart illustrating a method of making a device.

FIG. 8 illustrates a method of using a device according to one embodiment.

FIG. 9 illustrates a method of suing a device according to another embodiment.

### SUMMARY OF THE INVENTION

A communication device comprising an integrated circuit operable to signal process a baseband signal and output a control signal according to a communication protocol; a radio frequency integrated circuit (RFIC) operable to mix the baseband signal with a local oscillator to modulate an radio frequency (RF) carrier with the baseband signal or demodulate the baseband signal from an RF signal; an antenna having a feed to receive the RF carrier or output the RF signal; an RF switch; a solid state power amplifier coupled between the RF switch and the RFIC and operable to amplify the RF carrier; a low noise amplifier coupled between the RF switch and the RF input and operable to amplify the RF signal; wherein the control signal controls the RF switch to select between a transmission mode and a reception mode according to the communication protocol executed in the integrated circuit.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

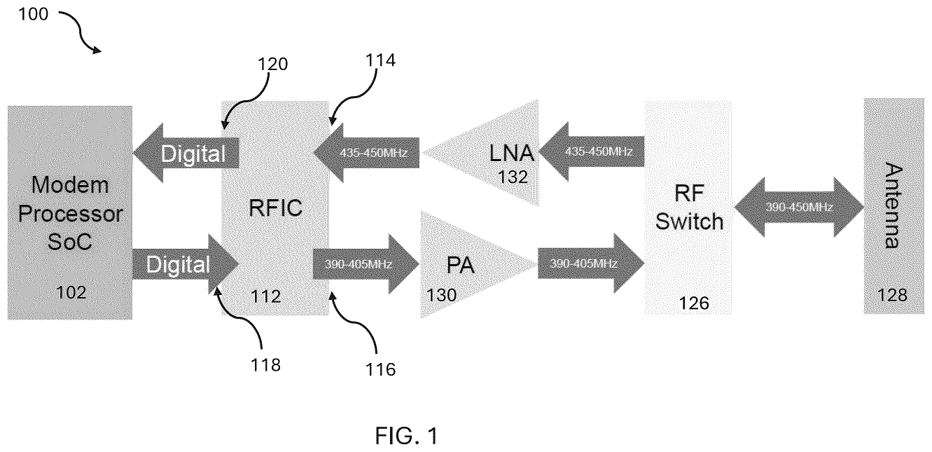

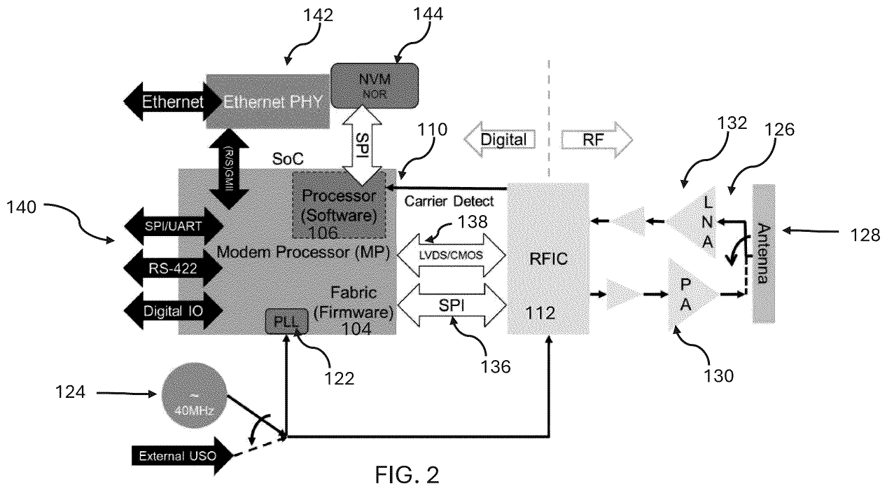

FIG. 1 illustrates a communication device 100 comprises an integrated circuit (e.g., system on a chip or system-on-chip SoC) which is operable to signal process a baseband signal and output a control signal according to a communication protocol (typically satellite communication protocol). The integrated circuit 102 comprises a system on a chip or system on chip (SoC) and/or (or including) programmable logic fabric 104, such as a Field Programmable Gate Array (FPGA) (e.g., polarfire), configured to encode (information in) and decode (information from) the baseband signal, e.g., in real time, and to generate the control signal, and a programmable controller 106, such as an Application Specific Integrated Circuit (ASIC) (e.g., Reduced Instruction Set (RISC), or RISC central processing unit CPU), operable to execute the communication protocol and determine timing of the control signal. The programmable logic fabric 104 can receive the timing of the control signal via an on-chip bus. The integrated circuit comprises at least one port 140 configured to receive and output the information, and an output (not shown) configured to output the control signal according to a communication protocol.

The programmable controller 106 further comprises an input 110 configured to receive a carrier detect signal from a Radio Frequency Integrated Circuit (RFIC) 112, the carrier detect signal indicating the presence of an incoming RF signal and used by the programmable controller 106 to determine timing of the control signal according to the communication protocol.

The RFIC 112 is operable to mix the baseband signal with a local oscillator to modulate an RF carrier or demodulate the baseband signal from an RF signal. The RFIC 112 comprises an RF input 114 for receiving the RF signal, an RF output 116 for outputting the RF carrier, a baseband input 118 configured to receive the baseband signal from the SoC 102, and a baseband output 120 for outputting the demodulated baseband signal to the SoC 102.

A phase-locked loop (PLL) 122 is operatively coupled to the RFIC 112. The PLL 122 is coupled to an (e.g., external) clock source 124 comprising a temperature-compensated crystal oscillator (TCXO) or an ultra-stable oscillator (USO), and is operable to generate a reference signal controlling a frequency of the local oscillator in the RFIC 112. The external clock source 124 provides a 40 MHz reference signal to the PLL 122.

The device further comprises at least one antenna 128 having a feed configured to receive the RF carrier and operable to output first electromagnetic radiation in response thereto; or configured to output an RF signal in response to second electromagnetic radiation received on the antenna.

The device 100 further comprises an RF switch 126 operable to switch connection, in response to the control signal from the SoC 102, between a feed of the antenna 128 and the RF output 116 in a transmission mode, or the RF input 114 in a reception mode. The control signal controls the RF switch 126 to select between the transmission mode and the reception mode according to the communication protocol executed in the SoC 102. The device 100 does not include a diplexer, thereby reducing mass and complexity.

A solid state power amplifier (SSPA) 130 is coupled between the RF switch 126 and the RF output 116 and is operable to amplify the RF carrier. In one embodiment, the SSPA 130 is operable to produce at least 2 watts of RF output power at a power-added efficiency of greater than 50 percent. For example, the CMX902 SSPA chip has been tested to produce 2 W of RF power with only 4W of power consumption, representing 50% efficiency compared to the prior state-of-the-art which operated at 30% efficiency. A low noise amplifier (LNA) 132 is coupled between the RF switch 126 and the RF input 114 and is operable to amplify the RF signal.

In one or more embodiments, the RF signal and RF carrier have a frequency in the UHF or S frequency band, e.g., in the 390-450 MHz range for transmit and 435-450 MHz for receive, although other frequency ranges are possible. At least one transmit filter 134 is operatively coupled between the RFIC 112 and the SSPA 130. The transmit filter 134 is configured to suppress frequencies outside the desired transmit band. In one or more embodiments, only the SSPA 130, LNA 132, and antenna 128 are frequency specific components. The SoC 102 and RFIC 112 can be operable to support multiple frequency bands by reconfiguring the programmable logic fabric 104 and reprogramming the RFIC 112 via the serial interface 136 without hardware modification. The programmable logic fabric 104 is configurable at a hardware level by loading a configuration bitstream and the programmable controller 106 is programmable at a software level by executing software instructions, wherein the configuration bitstream and the software instructions are each independently updatable.

A variety of connections between the SoC and the RFIC are possible. In one embodiment, a serial interface 136 connects the SoC 102 to the RFIC 112 for configuration and control of the RFIC 112, and a parallel interface 138 connects the SoC 102 to the RFIC input 118 for transfer of the baseband signal. The SoC 102 further comprises an external interface 140, e.g., including at least one of RS-422, Ethernet, SGMII, or SPI, the interface 140 configured to communicate with the computer of the platform (e.g., spacecraft, UAV, drone, satellite) on which the communication device is mounted. For this purpose, an Ethernet PHY 142 can be operatively coupled to the SoC 102 to support Ethernet communications. The device can further comprise a memory 144, such as non-volatile memory (NVM) flash, storing at least one of a configuration bitstream for the programmable logic fabric 104 or executable software for the programmable controller 106.

### Packaging/PCB Mounting

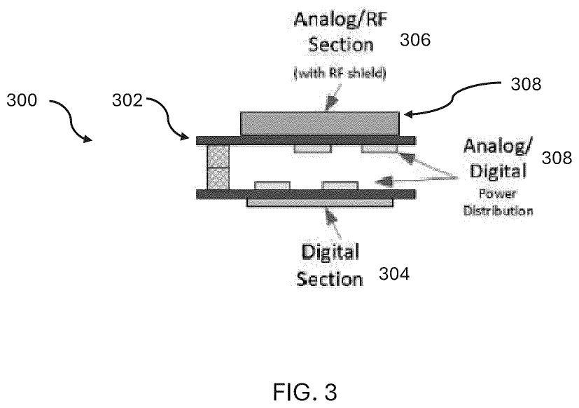

FIG. 3 illustrates the device 100 components mounted as a package 300 on one or more printed circuit boards 302 partitioned into a digital section 304, comprising the SoC 102 and associated memory (144), and an analog and RF section 306 comprising the RFIC 112 and RF switch 126 shielded by RF shield 308. The SoC 102 has a footprint of 23 mm by 23 mm on the printed circuit board 200. The shielded analog and RF section 206 further includes the amplifiers. Analog/digital power distribution components 310 are also provided on the printed circuit board 302. In one or more embodiments, the SoC 102 is a radiation-tolerant device tolerant to at least 100 krad total ionizing dose.

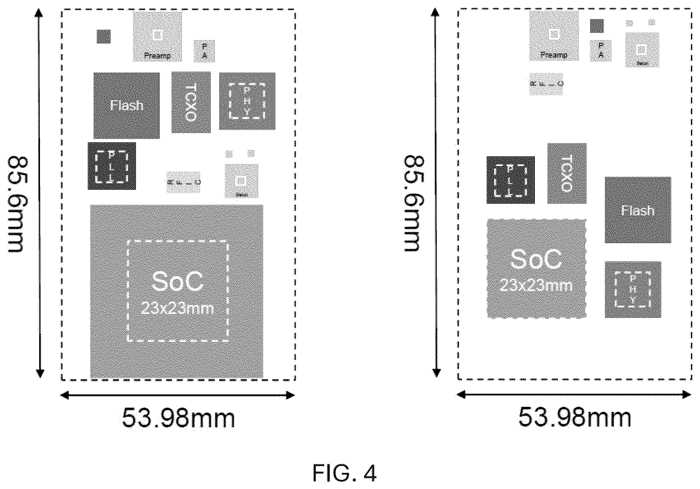

FIG. 4 illustrates example PCB component layouts. As shown, the device 100 mounted on the PCB can have a reduced footprint, e.g., with dimensions of 85.6 mm by 53.98 mm (or an area less than 100 mm by 100 mm). In some embodiments, the device 100 has a total stack mass of less than 300 grams and a total DC power consumption of less than 10 watts.

### Example Communication System

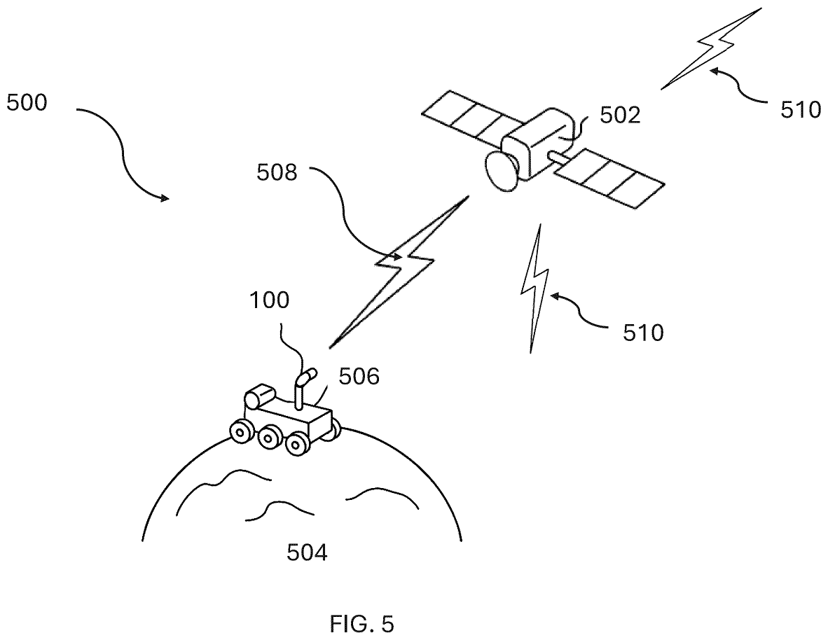

FIG. 5 illustrates an example communication system 500 comprising one or more satellites 502 (e.g., a relay) in orbit around a planet 504; and one or more unmanned or manned vehicles 506 on the planet and each carrying the transponder as described herein. The unmanned vehicles each communicate directly with the satellites via the electromagnetic radiation 508 transmitted and received by transponder 100. The communication can be stored on satellite for re-transmission 510 (e.g., at a later time) to the planet or another planet (e.g., from Mars to Earth).

In one or more embodiments, the transponder communication 508 can exchange several types of signals that together support communication, control, and positioning of an unmanned vehicles. These signals typically include command signals, telemetry signals, ranging signals, remote sensing, scientific data, and/or navigation-related signals. Command signals may carry control instructions sent to the vehicle or spacecraft, allowing remote systems to direct operation, change modes, or initiate acts. Telemetry signals may carry status information from the vehicle or spacecraft, such as health, sensor readings, and operational data, enabling monitoring and supervision. Ranging signals may be used to determine distance by measuring signal travel time between the transponder and a remote satellite, supporting tracking and orbital or positional determination, or other information required for modulating the transmission. Navigation-related signals (often derived from ranging, Doppler shift, or timing measurements) can support estimation of position, velocity, and movement of the vehicle relative to other nodes in the system.

In one or more embodiments, the SoC including the modem can be reconfigured with adaptive waveforms to change the type of modulation and signal structure used to transmit data based on current communication conditions encountered during satellite communication. For satellite links, these conditions typically include short visibility windows, large and rapidly changing distances, and relative motion that introduces Doppler frequency shifts. The SoC including the modem selects among robust modulation schemes, such as binary phase-shift keying (BPSK) or similar low-order modulations, when conditions are difficult-such as during weak signal strength, high Doppler shift, or the beginning and end of a satellite pass. When conditions improve, such as near the peak of a visibility window where signal quality is higher, the modem may switch to more efficient modulation to increase data throughput.

In one or more embodiments, the adaptive behavior allows reliable communication during brief contact windows, supports accurate timing and ranging measurements, and maintains signal integrity despite frequency and timing changes caused by satellite motion. In this way, adaptive waveforms and modulation enable a mobile or low-power device to communicate effectively with a fast-moving satellite relay without requiring continuous connectivity.

In one or more embodiments, the SoC can implement a Carrier Tracking Loop. When the RFIC downconverts the received RF signal to baseband, the resulting baseband signal may contain a residual frequency and phase error because the local oscillator in the RFIC may not perfectly synchronized to the carrier frequency of the transmitting satellite. Additionally the Doppler shift caused by the relative motion of the relay satellite can continuously shift the received carrier frequency away from the nominal value. The carrier tracking loop can be a digital feedback algorithm implemented in the programmable logic fabric that continuously measures this residual frequency and phase error by examining the received baseband samples, and applies a corresponding frequency and phase correction to bring the received signal into alignment with the expected carrier. In some embodiments, without this correction the demodulator cannot reliably determine which phase state each received symbol is in and therefore cannot correctly decode the transmitted bits. In some embodiments, the carrier tracking loop must operate continuously in real time at the baseband sample rate, updating its frequency and phase correction estimate on every sample or every symbol, which is why it must/may be in these examples implemented in the parallel processing architecture of the FPGA rather than in sequential software running on the programmable controller.

In some embodiments, the SoC can implement Symbol Timing Recovery to determine exactly when each transmitted symbol begins and ends in the stream of received baseband samples. Because the transmitter and receiver clocks may not be perfectly synchronized, and because the Doppler shift also affects the apparent symbol rate, the receiver must/may, in some embodiments, continuously track the symbol timing and adjust its sampling instants to sample each symbol at its optimum point. Like the carrier tracking loop this must/may in some embodiments operate in real time at the sample rate and can therefore be implemented in the programmable logic fabric.

In some embodiments, the SoC can implement a Forward Error Correction Encoder and Decoder, where the transmitter adds mathematically structured redundancy to the data bits before modulation, in a process called encoding, so that the receiver can detect and correct bit errors that occur during transmission without requiring retransmission of the data. The encoder takes the original data bits and produces a larger number of coded bits according to a specific mathematical coding scheme such as convolutional coding, turbo coding, or Low density parity check (LDPC).

In some embodiments, the SoC can implement a Frame Synchronizer, wherein the transmitted data is organized into structured packets or frames, where each frame begins with a known synchronization marker, also called a sync word or frame sync pattern, followed by the data payload and any header or trailer fields defined by the communication protocol. The frame synchronizer in the programmable logic fabric can search the stream of decoded bits for the known synchronization pattern, identify the frame boundaries, and extracts the data payload from each frame for delivery to the programmable controller. In some embodiments, without frame synchronization the receiver cannot determine where one frame ends and the next begins and cannot correctly interpret the received data. The frame synchronizer must/may in some embodiments also handle cases where the received bit stream is inverted in polarity, which can happen depending on the phase ambiguity resolution of the carrier tracking loop, by detecting the sync pattern in both its normal and inverted forms.

In some embodiments, the SoC can implement a Ranging Tone Generator and Processor generating a ranging tone, which is a known signal at a specific frequency or with a specific pattern, that is transmitted along with or instead of the data signal. The receiver at the relay satellite receives this ranging tone, and the relay satellite transponder retransmits a coherent version of it back to the surface platform. The surface platform then measures the round trip propagation delay of the ranging tone to determine the distance to the relay satellite. The ranging tone generator in the programmable logic fabric produces the ranging signal according to the specifications of the communication (e.g., Proximity-1) standard, and the ranging processor measures the round trip delay with sufficient precision for navigation purposes.

In some embodiments, the SoC can implement a Protocol State Machine implementing the sequence of states and transitions defined by the communication (e.g., Proximity-1) protocol for managing a communication session from initial link acquisition through data transfer to link release. It coordinates the timing of the RF switch control signal, the activation of the carrier tracking loop and frame synchronizer, the initiation of ranging operations, and the handover of data to and from the programmable controller. The state machine runs in the programmable logic fabric in coordination with the programmable controller, with the real time signal processing states managed in the programmable logic fabric and the higher level protocol management states managed in the programmable controller software via the on-chip bus.

In some embodiments, the SoC can implement a configuration bitstream comprising the binary file that is loaded into the FPGA programmable logic fabric at startup to define its internal hardware architecture. Loading a different configuration bitstream changes the hardware architecture of the FPGA so that the reconfigurable logic fabric can implement fundamentally different waveforms, modulation schemes, and coding schemes by loading different configuration bitstreams, whereas a fixed function RFIC or ASIC may not be reconfigured in this way. The configuration bitstream can be stored in the non-volatile memory on the printed circuit board and loaded into the FPGA at power-on, and can be updated by writing a new bitstream to the non-volatile memory via the external interfaces of the device.

In some embodiments, the SoC can be programmable by loading or updating software, digital processing algorithms, firmware, logic, or other algorithms after deployment of the unmanned vehicle. New rules, logic, or (e.g., adaptive) waveforms or decision-making protocols can be altered (updating how modulation decisions are made, adding support for new waveforms or protocols). Thus, decisions on how bits are mapped onto the carrier, the modulation scheme used (e.g., BPSK, QPSK), the symbol structure used during transmission, or other processing as described herein can be updated.

In some embodiments, the SOC can be programmed to implement a variety of communication protocols such as, but not limited to, Proximity-1 or other satellite communication protocol designed for two-way radio links between planetary assets, or between space assets or between surface/planet assets such as a surface vehicle, aerial vehicle, drone, or lander, or autonomous vehicles and the passing space assets such as relay satellite. The protocol can be in some embodiments specifically intended to operate during brief visibility windows caused by satellite motion and therefore can take into account relative movement, changing geometry, and Doppler frequency shifts between the communicating nodes. The protocols may support reliable delivery of commands, telemetry, and science/remote sensing data during those passes. The satellites can be part of a relay (e.g., Mars Relay Network) for storing and forwarding the information/communication/internet data, data center data to another region of the planet (e.g., Earth), to another planet, or another vehicle or ground station on the planet at a convenient time. Examples of the satellite include, but are not limited to, spacecraft, space stations, data centers (e.g., comprising computers or servers for artificial intelligence/machine learning processing), or space platforms such as small footprint satellites such as CubeSats.

Examples of manned or unmanned vehicles 506 include autonomous/self driving vehicles (e. g, cars) that can move on land, sea or air, such as drones, unmanned aerial vehicles (aircraft, helicopters), land rovers or other vehicles with wheels for driving on land (e.g., trucks, cars), submersibles, submarines, boats, space platforms such as satellites, spacecraft, or space stations etc. that can be autonomous or remote controlled. The vehicles can also be manned or transport passengers, in some embodiments.

Although illustrated on a unmanned vehicle UAV, UGV, it could be implemented in any system, such as structure, system, or infrastructure (building) or space platform or satellite, or space station. The vehicles 600 can also be manned or contains/transport passengers, in some examples.

The device 100 can be configured to communicate directly with a remote node in a communication network using the communication protocol without requiring an intermediate relay between the device 100 and the remote node. The remote node can be an orbital relay satellite, a ground station, or another space platform, for example.

### Example Radar or Software Defined Radio System or Software Defined Radar

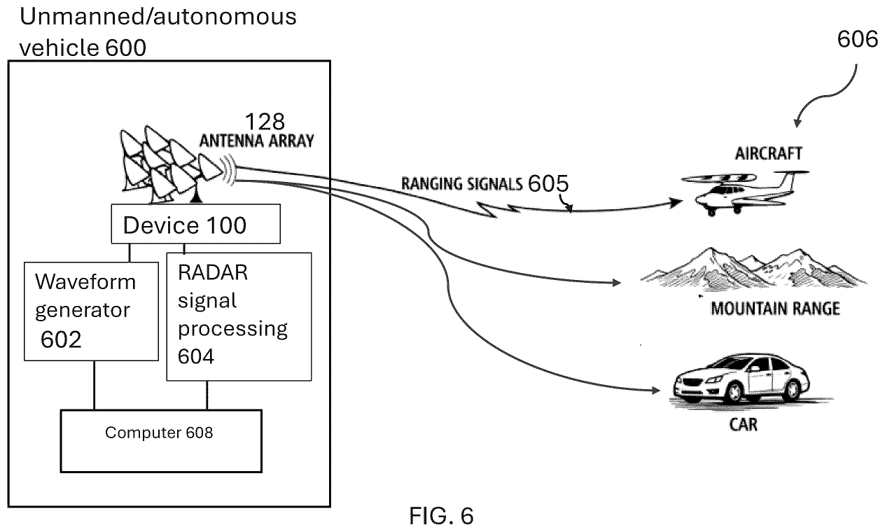

FIG. 6 illustrates a RADAR system or Software Defined Radio/Software Defined Radar system comprising the device 100 configured, e.g., as a transponder, e.g., that may be located on unmanned or autonomous vehicle 600 or any other platform or system. The device is coupled to circuitry operable as waveform generator 602 and Radar signal processing 604 for transmitting and processing ranging or radar signals 605.

The waveform, signal processing, and operating parameters of the radar signal/electromagnetic radiation 605 can be implemented in reconfigurable software and firmware executed on the integrated circuit 102. In this way, adaptive beam forming or other programming of the radar signal can be implemented. The waveform generator 602 and radar signal processor 604 can be on chip or coupled to the device. The SoC/FPGA can be programmed to implement the waveform (synthesized by waveform generator 602) used to generate the radar signal/electromagnetic radiation (e.g., adaptive beamforming) emitted from the antenna array 128, demodulate the radar signal received in response to the adaptive beamforming for signal processing by RADAR signal processing unit 604. The radar signals can be programmed by SOC for self driving/navigation/collision avoidance purposes on a self driving/autonomous vehicle, and can be configured for ranging or location of surrounding objects 606 such as a car, aircraft, or terrain. A computer 608 can also be on the unmanned vehicle for further control or any computing needs of the vehicle 600. Although illustrated on a unmanned vehicle, it could be implemented in any system, such as structure, system, or infrastructure (building) or space platform or satellite, or space station. The vehicles 600 can also be manned or contains passengers, in some examples.

### Process Steps

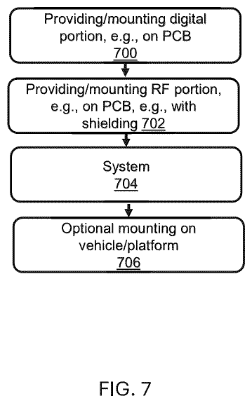

FIG. 7 is a flowchart illustrating a method of making a communication device, comprising the following steps.
Block 700 represents providing/fabricating an integrated circuit in a digital section, e.g., of a printed circuit board (PCB), the integrated circuit programmable to signal process a baseband signal and output a control signal according to a communication protocol.
Block 702 represents providing/fabricating on an RF section of the PCB or another PCB board:
an radio frequency integrated circuit (RFIC), the RFIC operable to mix the baseband signal with a local oscillator to modulate an RF carrier with the baseband signal or demodulate the baseband signal from an RF signal;
an antenna operable having a feed to receive the RF carrier or output the RF signal;
an RF switch, e.g., radio frequency switch capable of switching radio frequency signals.
a solid state power amplifier coupled between the RF switch and the RFIC and operable to amplify the RF carrier;
a low noise amplifier coupled between the RF switch and the RF input and operable to amplify the RF signal;
wherein the control signal controls the RF switch to select between a transmission mode and reception mode according to the communication protocol executed in the integrated circuit;
Block 704 represents the resulting system.
Block 706 represents optional mounting the printed circuit board on a vehicle (e.g., unmanned aerial vehicle (UAV), unmanned ground vehicle (UGV), unmanned marine vehicle, or any other platform,, vehicle (e.g., self driving car or truck) or satellite, system, or infrastructure.

Illustrative embodiments of the system include, but are not limited to, the following.
1.A communication device, comprising:
an integrated circuit programmable to signal process a baseband signal and output a control signal according to a communication protocol;
a radio frequency integrated circuit (RFIC) operable to mix the baseband signal with a local oscillator to modulate an RF carrier with the baseband signal or demodulate the baseband signal from a radio frequency (RF) signal;
an antenna operable having a feed to receive the RF carrier or output the RF signal;
an RF switch;
a solid state power amplifier coupled between the RF switch and the RFIC and operable to amplify the RF carrier;
a (e.g., low noise) amplifier coupled between the RF switch and the RF input and operable to amplify the RF signal;

wherein the control signal controls the RF switch to select between a transmission mode and reception mode according to the communication protocol executed in the integrated circuit.
2. The communication device of clause 1 wherein the integrated circuit is a system on chip comprising a programmable logic fabric comprising a field programmable gate array (FPGA) configured to encode and decode the baseband signal in real time and to generate the control signal, and a programmable controller comprising an application specific integrated circuit (ASIC) operable to execute the communication protocol determining timing of the control signal, wherein the programmable logic fabric receives the timing of the control signal via an on-chip bus.
3. The device of clause 1 or 2, wherein the communication protocol is Proximity-1 protocol.
4. The device of any of the clauses 1-3, wherein the device has a total stack mass of less than 300 grams and/or total DC power consumption of the device is less than 10 watts, and/or implemented on printed circuit board having dimensions no greater than 100 mm by 100 mm.
5. The device of any of the clauses 1-4, wherein the power amplifier is operable to produce at least 2 watts of RF output power at a power-added efficiency of greater than 50 percent.
6. The device of any of the clauses 1-5, wherein the RF signal and RF carrier have a frequency in a UHF or S frequency band.
7. The device of any of the clauses 1-6, wherein the integrated circuit is a radiation-tolerant device tolerant to at least 100 krad total ionizing dose.
8. The device of any of the clauses 1-7, further comprising a phase-locked loop (PLL) operatively coupled to the RFIC, the PLL coupled to an external clock source comprising a temperature-compensated crystal oscillator or an ultra-stable oscillator, and the PLL operable to generate a reference signal controlling a frequency of the local oscillator in the RFIC.
9. The device of any of the clauses 1-8 further comprising at least one transmit filter operatively coupled between the RFIC and the power amplifier, the transmit filter configured to suppress frequencies outside the desired transmit band.
10. The device of any of the clauses 1-9, wherein the integrated circuit comprises an interface including at least one of RS-422, Ethernet, SGMII, or SPI, the interface configured to communicate with a spacecraft or platform computer.
11. The device of any of the clauses 1-10, comprising a serial interface connecting the integrated circuit to the RFIC for configuration and control of the RFIC, and a parallel interface connecting the integrated circuit to the RFIC input for transfer of the baseband signal.
12. The device of any of the clauses 1 -11 wherein the device is configured to communicate directly with a remote node in a communication network using the communication protocol without requiring an intermediate relay between the device and the remote node, wherein the remote node can be an orbital relay satellite, a ground station, or another space (e.g., deep space) platform.
13. The device of any of the clauses 1-12, wherein the device is mounted on a printed circuit board partitioned into a digital section comprising the integrated circuit and associated memory, and a shielded analog and RF section comprising the RFIC and RF switch, the memory comprising non-volatile memory storing at least one of a configuration bitstream for the programmable logic fabric and executable software for the programmable controller.
14. The device of any of the clauses 1-13, wherein the device does not include a diplexer and/or the device does not include a duplexer.
15. A satellite communication system comprising the device of any of the clauses 1-14.
16., An autonomous vehicle comprising the device of any of the clauses 1-15.
17. A RADAR system comprising the device of any of the clauses 1-16.
18. A software defined radio or software defined radar comprising or coupled to the device of any of the clauses 1-17.
19. The device of any of the clauses 1-18 wherein the programmable controller comprises an input configured to receive a carrier detect signal from the RFIC, the carrier detect signal indicating presence of an incoming RF signal and used by the programmable controller to determine timing of the control signal according to the communication protocol.
20. The device of any of the clauses 1-19 wherein only the power amplifier, low noise amplifier, and antenna are frequency specific components, and wherein the integrated circuit and RFIC are operable to support multiple frequency bands by reconfiguring the programmable logic fabric and reprogramming the RFIC via a serial interface without hardware modification.
21. The device of any of the clauses 1-20 wherein the programmable logic fabric is configurable at a hardware level by loading a configuration bitstream and the programmable controller is programmable at a software level by executing software instructions, wherein the configuration bitstream and the software instructions are each independently updatable.
22. The device of any of the clauses 1 -21 comprising or configured as a transponder.
23. A communication system comprising the transponder of clause 22, comprising:
one or more satellites in orbit'around a planet;
one or more unmanned vehicles on the planet and each coupled to the transponder of clause 22, wherein the unmanned vehicles communicate directly with the satellites via the transponder.
23. The method of FIG. 7 used to make the device of any of the clauses 1-22.
24. The device of any of the clauses 1-23, wherein the device and vehicle are small size weight and power (SWAP) devices.
25. The device of any of the clauses 1-24, wherein the device comprises a chip or system on chip (SoC), and or the integrated circuit 102 comprises a SoC.
26. A method of transmitting signals to a satellite, comprising: using a transponder (e.g., comprising the device of any of the clauses 1-25) on an unmanned vehicle programmed to communicate directly with an orbiting satellite using a satellite communication protocol.
27. A method of transmitting signals for radar, comprising:

Using a transponder (e.g., comprising the device of any of the clauses 1-25) on a (e.g., self driving/flying/navigating or remote controlled) vehicle programmed to transmit and demodulate ranging signals for software defined radio.
28. A method of making a communication device (e.g., comprising the device of any of the clauses 1-25), comprising:
Providing an integrated circuit in a digital section of a printed circuit board, the integrated circuit programmable to signal process a baseband signal and output a control signal according to a communication protocol;
Providing an radio frequency integrated circuit (RFIC) in an RF section of the printed circuit board, the RFIC operable to mix the baseband signal with a local oscillator to modulate an RF carrier with the baseband signal or demodulate the baseband signal from an RF signal;
Positioning, on the RF section:
an antenna operable having a feed to receive the RF carrier or output the RF signal;
an RF switch;
a solid state power amplifier coupled between the RF switch and the RFIC and operable to amplify the RF carrier;
a low noise amplifier coupled between the RF switch and the RF input and operable to amplify the RF signal;
wherein the control signal controls the radio frequency (RF) switch to select between a transmission mode and reception mode according to the communication protocol executed in the integrated circuit;
mounting the printed circuit board on an (e.g., unmanned) vehicle.
29. The device of any of the clauses 1-28, wherein integrated circuit includes fabric 104 and processor 106.
30. The device of any of the clauses 1-29, wherein the RF frequency of RF signal is in a range of 3 kHz to 1000 GHz.

### Method of Use

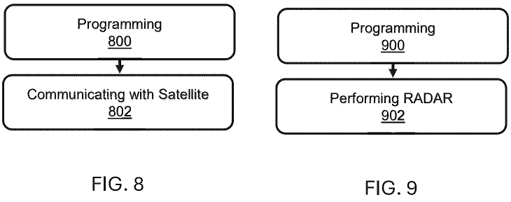

FIG. 8 is s a flowchart illustrating a method of transmitting signals to, and communicating with, a satellite, comprising the following steps.
Block 800 represents programming the communication device 100 (e.g., transponder) to communicate directly with an orbiting satellite using a satellite communication protocol;
Block 802 represents mounting the communication device on a vehicle and using the programmed communication device to communicate directly with an orbiting satellite using a satellite communication protocol.

FIG. 9 is a flowchart illustrating a method of transmitting signals for radar, comprising the following steps.
Block 900 represents programming the device 100 (e.g., transponder) to perform RADAR;
Block 902 represents using the programmed device (e. g,. transponder), e.g., mounted on an unmanned vehicle to transmit and receive (and optionally demodulate) ranging signals for software defined radio or software defined radar.

The methods of communicating and/or performing radar can use device 100 of any of the embodiments described herein, e.g., including those in clauses 1-30 above. The device can perform both methods, in some embodiments.

### Advantages and Improvements

By utilizing RFIC technology, it is possible to eliminate much of the bulky components at UHF such as discrete switches, mixers, and filters, allowing for a significant mass reduction. This mass reduction was enabling for the Ingenuity telecom solution and is likewise enabling for the present invention.

By utilizing a mainly digital approach, it is possible to minimize the distortions experienced in the traditional modulator and demodulator chains, thereby improving performance.

By utilizing a low-power FPGA relative to the aging Virtex-5 in existing designs, and modern SSPA technology such as GaN or GaAs, the overall power consumption of the transponder is reduced considerably.

One major benefit of the highly integrated approach is that the transponder is greatly simplified in terms of part count, while utilizing a heritage-inspired design that was tested as part of Mars 2020.

While a diplexer requires an additional 200 g, embodiments of the present transponder takes a half-duplex approach to minimize size and weight. Additionally, due to the lack of thermal management capacity in small platforms, the transponder only generates 2 W of RF power compared to Electra-Lite's 8 W. Power amplifiers are generally inefficient at around 30% efficiency, and while a high efficiency power amplifier of greater than 50% efficiency is utilized, there remains a limit on thermal power dissipation that the platform can tolerate. For reference, the Ingenuity helicopter, which only supported surface-to-surface communication, utilized a 1 W RF output amplifier. The use of a half-duplex approach eliminates the need for a diplexer, saving approximately 200 g in mass.

The flexibility of the programmable logic fabric allows any new waveforms to be implemented without hardware modification, as only the LNA, SSPA, and antenna are frequency specific components. This enables the device to support multiple frequency bands and directly inherit functionality from prior missions such as MarCO and Mars Sample Return.

The Ingenuity/Perseverance 915 MHz telecommunication link, in which the telecom solution comprised a microcontroller connected to an RFIC transceiver chip that modulated the signal according to the 802.15.4 standard using a fixed function RFIC. This was then connected to a low-noise amplifier and solid-state-power-amplifier front-end chip and subsequently to the antenna. A distinction in the present design is the interface between the FPGA and the RFIC, which enables flexibility in the frequency plan and multiple band support, and most importantly allows leveraging of heritage digital signal processing firmware and software to directly inherit functionality that has been thoroughly tested through prior mission development such as MarCO and Mars Sample Return. Additionally, any new waveforms can be implemented on the programmable logic fabric 104, and the device 100 is not limited to specific waveforms in the future. Moreover, the programmable FPGA allows modulation schemes required for satellite communications (e.g., proximity 1) to be implemented. Adaptive waveforms for satellite communication include dynamically selecting modulation schemes (such as BPSK) together with forward-error-correction strength, based on real-time measurements of link quality during short visibility windows and under Doppler shift. These techniques rely on continuous carrier and timing tracking to maintain synchronization and to support reliable demodulation, ranging, and data transfer despite satellite motion, and adjusting the modem adjusting the signal modulation in real time to maintain reliable communication as distance, movement, or signal quality changes.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is

1. A communication device, comprising:
an integrated circuit programmable to signal process a baseband signal and output a control signal according to a communication protocol;
a radio frequency integrated circuit (RFIC) operable to mix the baseband signal with a local oscillator to modulate an RF carrier with the baseband signal or demodulate the baseband signal from an RF signal;
an antenna operable having a feed to receive the RF carrier or output the RF signal;
an RF switch;
a solid state power amplifier coupled between the RF switch and the RFIC and operable to amplify the RF carrier;
a low noise amplifier coupled between the RF switch and the RF input and operable to amplify the RF signal;
wherein the control signal controls the RF switch to select between a transmission mode and reception mode according to the communication protocol executed in the integrated circuit.

2. The communication device of claim 1 wherein the integrated circuit is a system on chip comprising a programmable logic fabric comprising an FPGA configured to encode and decode the baseband signal in real time and to generate the control signal, and a programmable controller comprising an ASIC operable to execute the communication protocol determining timing of the control signal, wherein the programmable logic fabric receives the timing of the control signal via an on-chip bus.

3. The device of claim 1, wherein the communication protocol is Proximity-1 protocol.

4. The device of claim 1, wherein the device has a total stack mass of less than 300 grams and total DC power consumption of the device is less than 10 watts, and implemented on printed circuit board having dimensions no greater than 100 mm by 100 mm.

5. The device of claim 1, wherein the power amplifier is operable to produce at least 2 watts of RF output power at a power-added efficiency of greater than 50 percent.

6. The device of claim 1, wherein the RF signal and RF carrier have a frequency in a UHF or S frequency band.

7. The device of claim 1, wherein the integrated circuit is a radiation-tolerant device tolerant to at least 100 krad total ionizing dose.

8. The device of claim 1, further comprising a phase-locked loop (PLL) operatively coupled to the RFIC, the PLL coupled to an external clock source comprising a temperature-compensated crystal oscillator or an ultra-stable oscillator, and the PLL operable to generate a reference signal controlling a frequency of the local oscillator in the RFIC.

9. The device of claim 1 further comprising at least one transmit filter operatively coupled between the RFIC and the power amplifier, the transmit filter configured to suppress frequencies outside the desired transmit band.

10. The device of claim 1, further comprising at least one transmit filter operatively coupled between the RFIC and the power amplifier, the transmit filter configured to suppress frequencies outside the desired transmit band.

11. The device of claim 1, wherein the integrated circuit comprises an interface including at least one of RS-422, Ethernet, SGMII, or SPI, the interface configured to communicate with a spacecraft or platform computer.

12. The device of claim 1, comprising a serial interface connecting the integrated circuit to the RFIC for configuration and control of the RFIC, and a parallel interface connecting the integrated circuit to the RFIC input for transfer of the baseband signal.

13. The device of claim 1 wherein the device is configured to communicate directly with a remote node in a communication network using the communication protocol without requiring an intermediate relay between the device and the remote node, wherein the remote node can be an orbital relay satellite, a ground station, or another space platform.

14. The device of claim 1, wherein the device is mounted on a printed circuit board partitioned into a digital section comprising the integrated circuit and associated memory, and a shielded analog and RF section comprising the RFIC and RF switch, the memory comprising non-volatile memory storing at least one of a configuration bitstream for the programmable logic fabric and executable software for the programmable controller.

15. The device of claim 1, wherein the device does not include a diplexer.

16. A satellite communication system comprising the device of claim 1.

17. A software defined radio or radar comprising or coupled to the device of claim 1.

18. The device of claim 1 wherein the programmable controller comprises an input configured to receive a carrier detect signal from the RFIC, the carrier detect signal indicating presence of an incoming RF signal and used by the programmable controller to determine timing of the control signal according to the communication protocol.

19. The device of claim 3 wherein the programmable logic fabric is configurable at a hardware level by loading a configuration bitstream and the programmable controller is programmable at a software level by executing software instructions, wherein the configuration bitstream and the software instructions are each independently updatable.

20. The device of claim 1 configured as a transponder.
